(19) United States
(12) Patent Application Publication
(10) Pub. No.: US 2022/0270847 A1
(43) Pub. Date: Aug. 25, 2022

(54) CHARGED PARTICLE BEAM DEVICE

(71) Applicant: Hitachi High-Tech Corporation, Minato-ku, Tokyo (JP)

(72) Inventors: Kazuki Ikeda, Tokyo (JP); Wen Li, Tokyo (JP); Hajime Kawano, Tokyo (JP)

(21) Appl. No.: 17/632,837

(22) PCT Filed: Aug. 7, 2019
(86) PCT No.: PCT/JP2019/031055

§ 371 Date: Feb. 4, 2022

(51) Int. Cl. H01J 37/244; H01J 37/22; H01J 37/147

(52) U.S. Cl. CPC H01J 37/244; H01J 37/222; H01J 37/224; H01J 37/1474

(57) ABSTRACT

A multi-beam scanning electron microscope (charged particle beam device) 100 includes an electron gun (charged particle irradiation source) 101 configured to irradiate a sample 104 with an electron beam (charged particle beam) 103, a detector 106 having a detection region corresponding to the charged particle beam 103 and configured to output an electrical signal 107 corresponding to a reaching position when secondary particles 105 generated from the sample 104 by irradiating the sample 104 with the charged particle beam 103 reach the detection region, and a signal processing block 115 configured to perform measurement of a charge amount of the sample 104 by the charged particle beam 103 and generation of an inspection image of the sample 104 in parallel based on the electrical signal 107 output from the detector 106.

### TECHNICAL FIELD

The present invention relates to a charged particle beam device.

### BACKGROUND ART

As a background art of the present technology, for example, PTL 1 is disclosed. PTL 1 discloses an electron beam device that includes a unit that separates energy of electrons generated from a sample, a plurality of detection units, and a signal processing unit that processes addition and subtraction of the plurality of detection units to simultaneously acquire sample shape information and sample potential information and determine filtering conditions of secondary electrons for each irradiation condition of primary electrons.

Accordingly, a search time for the irradiation conditions and the filtering conditions can be shortened, and an optimum contrast can be obtained. In addition, charge is monitored in real time during observation to improve accuracy and reliability of a length measurement value.

### CITATION LIST

### Patent Literature

PTL 1: JP-A-2014-146526

### SUMMARY OF INVENTION

### Technical Problem

In semiconductor manufacturing process, miniaturization of a circuit pattern formed on a semiconductor substrate (wafer) has rapidly progressed, and importance of process monitoring for monitoring whether the pattern is formed as designed is increasing. For example, in order to detect an occurrence of disengagement such as an abnormality or a defect in the semiconductor manufacturing process at an early stage or in advance, measurement and inspection are performed on the circuit pattern or the like on the wafer at the end of each manufacturing step.

During the measurement and inspection, in a measurement and inspection device such as an electron microscope (SEM) using a scanning electron beam method and a corresponding measurement and inspection method, the wafer, which is a target sample, is irradiated with an electron beam while the wafer is scanned, and energy of secondary electrons generated thereby, electrons reflected by the sample, and the like are detected. Then, an image (a measurement image or an inspection image) is generated by performing signal processing and image processing based on the detected energy, and measurement, observation, and inspection are performed on the sample based on the image.

However, in the measurement and inspection device, improvement in throughput, which is inspection quantity per unit time, is required. In order to generate a secondary electron image in a short time, it is necessary to increase an irradiation amount of the electron beam. When the irradiation amount of the electron beam is increased, the sample may be charged, the image contrast in a secondary electron image may decrease, edge loss of the circuit pattern, or the like may occur, and inspection accuracy may decrease.

In PTL 1, the secondary electrons generated from the sample are detected by being separated by a plurality of detectors in accordance with the energy of the electrons, and calculation based on a detected signal is performed to measure a charge amount of the sample. In a method of PTL 1, a position where the secondary electrons reach the detector varies depending on a trajectory of the secondary electrons generated from the sample, and the secondary electrons are detected by the plurality of detectors regardless of the presence or absence of the charge, and thus the charge amount may be erroneously detected. On the other hand, in order to reduce the erroneous detection of the charge amount, it is necessary to use only the electrons with a limited trajectory as a detection target, but since a signal amount decreases, it may not be possible to obtain the secondary electron image sufficient for the inspection.

Accordingly, an object of the invention is to provide a charged particle beam device capable of achieving both improvement in throughput and maintenance of inspection accuracy.

### Solution to Problem

An outline of representative ones of the invention disclosed in the present application will be briefly described as follows.

A charged particle beam device according to representative aspects of the invention includes a charged particle irradiation source configured to irradiate a sample with a charged particle beam, a detector having a detection region corresponding to the charged particle beam and configured to output an electrical signal corresponding to a reaching position when secondary particles generated from the sample by irradiating the sample with the charged particle beam reach the detection region, and a signal processing block configured to perform measurement of a charge amount of the sample by the charged particle beam and generation of an inspection image of the sample in parallel based on the electrical signal output from the detector.

### Advantageous Effect

Effects obtained by representative ones of the invention disclosed in the present application will be briefly described as follows.

That is, according to the representative aspect of the invention, it is possible to achieve both the improvement in throughput and the maintenance of the inspection accuracy.

### BRIEF DESCRIPTION OF DRAWINGS

FIG. 1 is a block diagram showing an example of a configuration of a measurement, observation, and inspection device including a multi-beam scanning electron microscope according to a first embodiment of the invention.

FIG. 2 is a diagram showing an example of a configuration of a detector according to the first embodiment of the invention.

FIG. 3 is a diagram showing an example of a distribution of reaching positions of secondary particles according to the first embodiment of the invention.

FIG. 4 is a block diagram showing an example of a configuration of a signal processing block according to the first embodiment of the invention.

FIG. 5 is a flowchart showing an example of a method for measuring a charge amount and a method for generating an inspection image according to the first embodiment of the invention.

FIG. 6 is a diagram showing an example of a distribution of reaching positions of secondary particles according to a second embodiment of the invention.

FIG. 7 is a flowchart showing an example of a method for measuring a charge amount according to the showing as example of a configuration of a detector according to a third embodiment of the invention.

### DESCRIPTION OF EMBODIMENTS

Hereinafter, embodiments of the invention will be described with reference to the drawings. Each of the embodiments described below is an example for implementing the invention, and does not limit the technical scope of the invention. In the embodiments, members having the same function are designated by the same reference numeral, and repeated description thereof will be omitted unless particularly necessary.

### First Embodiment

### <Configuration of Measurement, Observation, and Inspection Device>

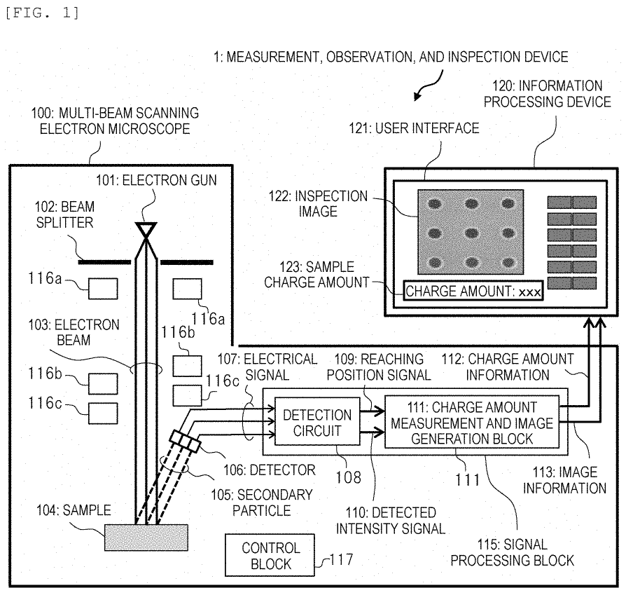

FIG. 1 is a block diagram showing an example of a configuration of a measurement, observation, and inspection device including a multi-beam scanning electron microscope according to a first embodiment of the invention. A measurement, observation, and inspection device 1 includes a multi-beam scanning electron microscope (charged particle beam device) 100 and an information processing device 120.

As shown in FIG. 1, the multi-beam scanning electron microscope 100 includes an electron gun (charged particle irradiation source) 101, a beam splitter 102, deflectors 116a, 116b, 116c, a detector 106, a detection circuit 108, a charge amount measurement and image generation block 111, a control block 117, and the like. Among these, the detection circuit 108 and the charge amount measurement and image generation block 111 constitute a signal processing block 115.

A sample 104 to be inspected is disposed below the electron gun 101 and the beam splitter 102. The sample 104 is placed on a stage (not shown). The electron gun 101 emits an electron beam (charged particle beam) 103 to a beam splitter 102 side. The electron gun 101 can simultaneously emit a plurality of electron beams.

The electron beam 103 is subjected to beam control by deflectors after passing through the beam splitter 102. For example, the electron beam 103 is emitted to the sample 104 after being subjected to control such as focusing by the deflector 116a, scanning by the deflector 116b, and beam amount adjustment (aperture) by the deflector 116c. A plurality of electron beams 103 are emitted in different directions. When the sample 104 is irradiated with the electron beam 103, secondary particles 105 such as secondary electrons are generated from the sample 104. In the following, a case where electrons are used as charged particles is described as an example. Since the electrons are very light particles, it is easy to control the beam by using the electrons as the charged particles. However, it is also possible to use particles other than the electrons as the charged particles.

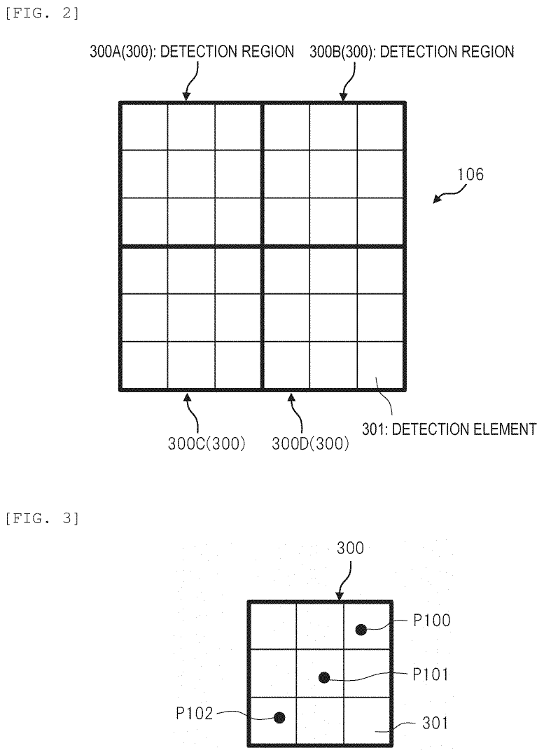

The detector 106 is a device that detects the secondary particles 105 generated from the sample 104. FIG. 2 is a diagram showing an example of a configuration of the detector according to the first embodiment of the invention. FIG. 2 shows a configuration of the detector 106 as viewed from an incident direction of the secondary particles 105. As shown in FIG. 2, the detector 106 includes a plurality of detection regions 300 (300A to 300D) corresponding to the respective electron beams. The detection region 300A corresponds to a first electron beam (also referred to as an electron beam A), and the detection region 300B corresponds to a second electron beam (also referred to as an electron beam B). The detection region 3005 corresponds to a third electron beam (also referred to as an electron beam C), and the detection region 300D corresponds to a fourth electron beam. (also referred to as an electron beam D). The secondary particles 105 generated by the respective electron beams reach corresponding detection regions and are detected.

A plurality detection elements 301 are two-dimensionally arranged in the respective detection regions 300 (300A to 300D). The respective detection elements 301 include, for example, a photoelectric conversion element such as a photomultiplier tube, a photodiode, or a phototransistor. When the secondary particles 105 generated from the sample 104 by being irradiated with the electron beam. 103 reach the detection region. 300, the detection element 301 where the secondary particles 105 reach outputs an electrical signal corresponding to a reaching position. That is, the respective detection elements 301 convert the incident secondary particles 105 into an analog electrical signal 107 by the photoelectric conversion element, and output the electrical signal 107 to the detection circuit 108.

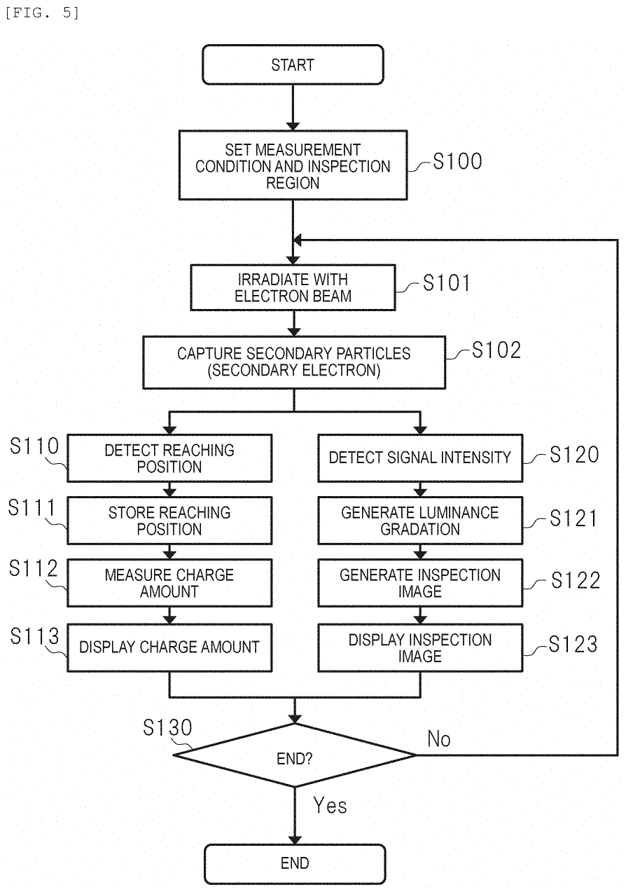

Specifically, output terminals of the respective detection elements 301 are connected to input terminals of corresponding reaching position detection circuits 1081 (FIG. 4) and input terminals of corresponding signal intensity detection circuits 1082 (FIG. 4). The electrical signal 107 output from the detection element 301 is output to the reaching position detection circuit 1081 and the signal intensity detection circuit 1082. Configurations of the reaching position detection circuit 1081 and the signal intensity detection circuit 1082 will be described in detail later. The respective detection elements 301 correspond to the reaching positions of the secondary particles 105, and the electrical signal 107 output from the detection element 301 is associated with the reaching position.

The number of the detection regions is not particularly limited, and is preferably equal to or larger than the number of the electron beams 103. In the example in FIG. 2, nine detection elements 301 are two-dimensionally arranged in each detection region 300, but the number of the detection elements 301 provided in each detection region 300 may be two or more. If there are at least two detection elements 301, a change in reaching position of the secondary particles 105 in the same detection region 300 can be detected. A range of the detection region 300 may be appropriately set according to a diffusion range of the secondary particles 105.

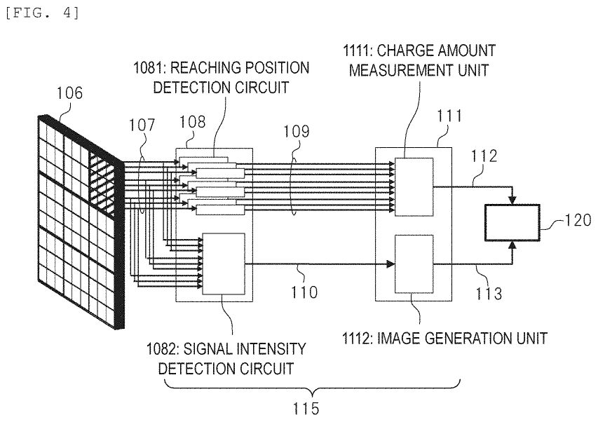

FIG. 3 is a diagram showing an example of a distribution reaching positions of the secondary particles according to the first embodiment of the invention. FIG. 3 shows reaching positions P100, P101, and P102 of the secondary particles 105 in one detection region 300. The reaching position P100 is included in a region of the detection element 301 at an upper right part of the detection region 300 in the figure, the reaching position P101 is included in a region of the detection element 301 at a center of the detection region 300, and the reaching position P102 is included in a region of the detection element 301 at a lower left part of the detection region 300. These are merely examples, and the secondary particles 105 are also incident on other detection elements 301 in the same detection region 300.

A shape of the detector 106 viewed from the incident direction of the secondary particles 105 is not limited to a quadrangle such as a square as shown in FIG. 2 and the like, and may be a polygon other than the quadrangle, or a shape including a curved line such as a circle or an ellipse. The shape of the detector 106 is not limited to a flat surface, or may be a shape in which a periphery is curved toward the sample 104 with respect to a center. An arrangement of the detection elements 301 is not limited to a grid pattern as shown in FIG. 2 and the like, or may be, for example, an arrangement in which positions of adjacent detection elements are shifted as in a honeycomb structure.

Next, the signal processing block 115 will be described. FIG. 4 is a block diagram showing an example of a configuration of the signal processing block according to the first embodiment of the invention. FIG. 4 shows the detector 106, the signal processing block 115, and the information processing device 120. The signal processing block 115 is a functional block that performs signal processing after the secondary particles 105 reach the detector 106. Specifically, the signal processing block 115 performs measurement of a charge amount of the sample 104 by the electron beam 103 and generation of an inspection image of the sample 104 in parallel based on the electrical signal 107.

The term “in parallel” as used herein includes not only a case where the measurement of the charge amount of the sample 104 and the generation of the inspection image of the sample 104 are started and ended at the same timing, but also a case where these types of processing are executed in parallel only for a part of the period. Specifically, the term also includes a case where one type or processing is started during execution of the other type of processing, and then executed in parallel, or a case where, when these types of processing are executed in parallel, one type of processing is ended and the other type of processing is continuously executed. In addition, the term “in parallel” may include processing a common processing resource (for example, a circuit or a processor) in a time division manner in a plurality types of processing or may include processing a plurality types of processing in parallel by using a plurality of processing resources.

As shown in FIG. 4, the signal processing block 115 includes the detection circuit 108 and the charge amount measurement and image generation block 111. The detection circuit 108 is a functional block that detects the reaching position of the secondary particles 105 and a signal intensity based on the electrical signal 107. The detection circuit 108 includes a plurality of reaching position detection circuits 1081 and a plurality of signal intensity detection circuits 1082. Although only a circuit configuration corresponding to one detection region 300 is shown in FIG. 4, circuits corresponding to all the detection regions 300 are actually provided.

The plurality of reaching position detection circuits 1081 are provided corresponding to the respective detection elements 301. The input terminals of the respective reaching position detection circuits 1081 are connected to the output terminals of the corresponding detection elements 301. That is, the respective reaching position detection circuits 1081 are connected to the corresponding detection elements 301 in a one-to-one manner. When the electrical signal 107 is input, the reaching position detection circuit 1081 detects the reaching position of the secondary particles 105 and generates a corresponding reaching position signal 109. The generated reaching position signal 109 is output to a charge amount measurement unit 1111 of the charge amount measurement and image generation block 111, which will be described later.

The reaching position detection circuit 1081 includes, for example, a comparator circuit that compares a voltage (amplitude) of the electrical signal 107 with a threshold voltage. When the voltage of the electrical signal 107 is higher than the threshold voltage, the reaching position detection circuit 1081 detects the input of the electrical signal 107 and generates and outputs the reaching position signal 109 which is a digital signal.

Information on the reaching position of the secondary particles 105 may be included in the reaching position signal 109. A wiring connecting the reaching position detection circuit 1081 and the charge amount measurement unit 1111 may be associated with the reaching position, and the reaching position of the secondary particles 105 may be specified by a wiring through which the reaching position signal 109 is input.

The plurality of signal intensity detection circuits 1082 are provided corresponding to the respective detection regions 300. The input terminals of the respective signal intensity detection circuits 1082 are connected to the output terminals of the plurality of detection elements 301 provided in the corresponding detection regions 300. The signal intensity detection circuit 1082 detects the signal intensity of the electrical signal 107 in the corresponding detection region 300, and generates a corresponding intensity signal 110. The generated intensity signal 110 is output to an image generation unit 1112 of the charge amount measurement and image generation block 111, which will be described later.

The signal intensity detection circuit 1082 includes, for example, an analog-digital converter, a plurality of addition circuits, and the like. The respective signal intensity detection circuits 1082 calculate, as the signal intensity, a sum of amplitudes of the electrical signals 107 output from all the detection elements 301 provided in the corresponding detection regions 300. Then, the signal intensity detection circuit 1082 outputs the calculated signal intensity as the intensity signal 110.

In this way, in the detection circuit 108, the detection of the reaching position of the secondary particles 105 by the respective reaching position detection circuits 1081 and the measurement of the signal intensity of the electrical signal 107 by each detection region 300 by the respective signal intensity detection circuits 1082 are performed in parallel.

The charge amount measurement and image generation block 111 is a functional block that performs the measurement of the charge amount of the sample 104 and the generation of the inspection image (generation of image information) in parallel. The charge amount measurement and image generation block 111 includes the charge amount measurement unit 1111 and the image generation unit 1112. The charge amount measurement and image generation block 111 includes, for example, a processor such as a CPU, the charge amount measurement unit 1111 is implemented by the processor executing a charge amount measurement program, and the image generation unit 1112 is implemented by the processor executing an image generation program. The charge amount measurement unit 1111 and the image generation unit 1112 may be constituted by a field-programmable gate array (FPGA), an application specific integrated circuit (ASIC), or the like.

The charge amount measurement unit 1111 measures the charge amount of the sample 104 based on the reaching position signal 109 output from the respective reaching position detection circuits 1081. The reaching position signal 109 may be stored in, for example, a storage device (not shown). The charge amount measurement unit 1111 detects a change in reaching position of the secondary particles 105 by using the reaching position signal 109, and measures the charge amount of the sample 104 based on the change in reaching position. For example, the charge amount measurement unit 1111 measures the charge amount by comparing a reaching position when the sample 104 is not charged with the detected reaching position. The charge amount measurement unit 1111 outputs the measured charge amount as charge amount information. 112 to the information processing device 120.

The image generation unit. 1112 generates the inspection image based on the intensity signal 110 for each detection region 300 output from the respective signal intensity detection circuits 1082. Specifically, the image generation unit 1112 generates, as the inspection image, image information 113 for displaying the inspection image on the information processing device 120 described later. The image generation unit 1112 outputs the generated image information 113 to the information processing device 120.

In this way, in the charge amount measurement and image generation block 111, the measurement of the charge amount by the charge amount measurement unit 1111 and the generation of the inspection image by the image generation unit 1112 are performed in parallel.

The control block 117 is a functional block that performs control related to an operation of the multi-beam scanning electron microscope 100. The control block 117 performs, for example, control of an operation of each component of the multi-beam scanning electron microscope 100, determination processing during the measurement of the charge amount and the generation of the inspection image, and the like.

The control block 117 includes, for example, a processor such as a CPU, and is implemented by executing a control program. Alternatively, the control block 117 may be constituted by an FPGA, an ASIC, or the like. All or a part of the control block. 117 may be integrated with the signal processing block 115 or a part of functions of the control block 117 may be implemented by the information processing device 120 described later.

The information processing device 120 is a device that displays the charge amount, the inspection image, and the like of the sample 104. For example, an information processing device having a display function such as a personal computer or a tablet terminal is used as the information processing device 120. A device having only a display function may be used as the information processing device 120.

As shown in FIG. 1, a user interface 121 is displayed on a display region of the information processing device 120. The user interface 121 displays, for example, a sample charge amount 123 based on the charge amount information 112 output from the charge amount measurement unit 1111, an inspection image 122 based on the image information 113 output from the image generation unit 1112, and the like. In addition, a setting content, an operation status, an operation panel, and the like of the multi-beam scanning electron microscope 100 may be displayed on the user interface 121. The information processing device 120 operates by executing a program executed by hardware or hardware.

### <Measurement of Charge Amount and Generation of Inspection Image>

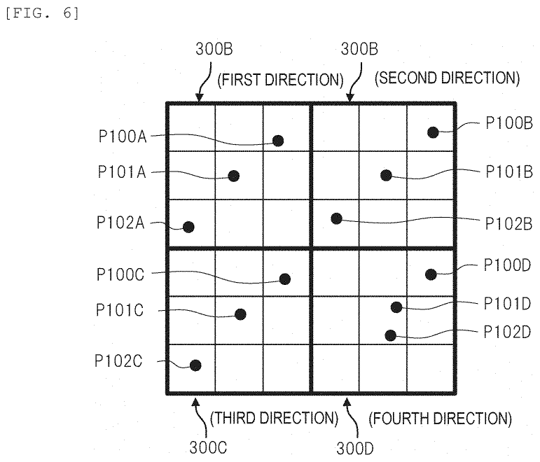

Next, a method for performing the measurement of the charge amount and the generation of the inspection image in parallel will be described. FIG. 5 is a flowchart showing an example of a method for measuring a charge amount and a method for generating an inspection image according to the first embodiment of the invention.

For the measurement of the charge amount and the generation of the inspection image, for example, processings of steps S100 to S102, steps S110 to S113, steps S120 to S123, and step S130 in FIG. 5 are performed. Among these steps, steps S110 to S113 are steps related to calculation and display of the charge amount of the sample. On the other hand, steps S120 to S123 are steps related to generation and display of the inspection image convenience of description, the measurement of the charge amount and the generation of the inspection image will be described separately, but are performed in parallel as shown in FIG. 5.

First, in step 3100, the multi-beam scanning electron microscope 100 is operated by using the operation panel or the like of the information processing device 120 to set a measurement condition and an inspection region for the sample 104. In the present embodiment, for example, a region corresponding to one of the detection regions 300 of the detector 106 is set as the inspection region. In this way, when only the region corresponding to one detection region. 300 is set as the inspection region, a single beam electron microscope can be used. The measurement condition include various conditions such as an intensity, an irradiation time, a scanning range, and the number of times of scanning related to the electron beam 103.

In step S101, the inspection region of the sample 104 is irradiated with the electron beam 103 based on the condition set in step S100. The multi-beam scanning electron microscope 100 irradiates the set inspection region with the electron beam 103 while scanning the set inspection region with the electron beam 103 by the deflector 116b or the like.

In step S102, the secondary particles 105 generated from the sample 104 reach the detector 106 and are captured. When the sample 104 is in a non-charged state, since a trajectory of the secondary particles 105 does not change, the reaching position of the secondary particles 105 is a predetermined reaching position (for example, P100 in FIG. 3) in the corresponding detection region 300.

On the other hand, when the sample 104 is charged by the irradiation with the electron beam 103, the trajectory of the secondary particles 105 is changed. As a result, the reaching position of the secondary particles 105 changes to P101 and P102 as the charge amount increases.

### <<Measurement of Charge Amount>>

In step S110, the reaching position of the secondary particles 105 is detected. The detection element 301 supplemented with the secondary particles 105 converts the secondary particles 105 into the electrical signal 107 which is an analog signal, and outputs the electrical signal 107 to the detection circuit 108. The electrical signal 107 output from the detection element 301 is input to the corresponding reaching position detection circuit 1081 and the corresponding signal intensity detection circuit 1082. The reaching position detection circuit 1081 detects the reaching position of the secondary particles 105 based on the input of the electrical signal 107, and outputs the corresponding reaching position signal 109 to the charge amount measurement unit 1111.

In step S111, the reaching position signal 109 is stored in the storage device. During the irradiation with the electron beam 103, a plurality of reaching position signals 109 are stored in the storage device.

The reaching position signal 109 may be stored in the storage device in association with a time output from the reaching position detection circuit 1081, a time input to the charge amount measurement unit 1111, or a storage time to the storage device (hereinafter, these will be collectively referred to as a “detection time”).

In step S112, the charge amount of the sample 104 is measured. The charge amount measurement unit 1111 detects the change in reaching position of the secondary particles 105 based on the reaching position signal 109 stored in the storage device, and calculates (measures) the charge amount of the sample 104 based on the change in reaching position. The charge amount measurement unit 1111 may detect a temporal change in reaching position to measure the charge amount based on the temporal change in reaching position.

The measurement of the charge amount is executed for each scanning range related to the electron beam 103. That is, the charge amount measurement unit 1111 measures the charge amount after the electron beam 103 is emitted in an entire range of the set inspection region. Accordingly, occurrence of irradiation unevenness of the electron beam 103 is reduced, and the unevenness of the charge amount in the inspection region is reduced.

The measurement of the charge amount is executed for every number of times of scanning with the electron beam 103. That is, the charge amount measurement unit 1111 measures the charge amount every time when the entire inspection region is scanned with the electron beam 103. In other words, when a plurality of times of scanning is set as the measurement condition, the charge amount measurement unit 1111 measures the charge amount corresponding to the number of times of scanning. Accordingly, the charge amount can be measured while adjusting the irradiation time of the electron beam 103 at a short interval.

If necessary, the same inspection region may irradiated with the electron beam 103 a plurality of times, and then the charge amount may be measured. Accordingly, the charge amount can be measured while freely changing the irradiation time of the electron beam.

In step S113, the charge amount measurement unit 1111 outputs, as the charge amount information. 112, the measured charge amount to the information processing device 120. The information processing device 120 displays the charge amount 123 of the sample on a predetermined region of the user interface 121 based on the input charge amount information 112. The charge amount measured in step S112 may be displayed as necessary, for example, when there is a request from a user. The measured charge amount may be stored in the storage device.

### <<Generation of Inspection Image>>

Next, the method for generating an inspection image will be described. In step S120, the signal intensity detection circuit 1062 converts, into the digital signals, the voltages (amplitudes) of all the electrical signals 107 output from the detection elements 301 in the corresponding detection region 300.

The signal intensity detection circuit 1082 adds the voltages of all the electrical signals 107 subjected to the digital conversion, and calculates the signal intensity in the corresponding detection region 300. The signal intensity detection circuit 1082 outputs the calculated signal intensity as the intensity signal 110, which is a digital signal, to the image generation unit 1112.

In the present embodiment, only the inspection region corresponding to one detection region 300 is irradiated with the electron beam 103. Therefore, the signal intensity of the other detection regions 300 corresponding to regions where the electron beam 103 is not irradiated is a value close to zero or a very small value.

Next, in step S121, the image generation unit 1112 generates a luminance gradation image of the region irradiated with the electron beam 103 based on the intensity signal 110 input from the signal intensity detection circuit 1082. While the scanning with the electron beam 103 is being performed, the image generation unit 1112 generates a plurality of luminance gradation images.

In step S122, the image generation unit 1112 generates an inspection image of the inspection region by arranging the plurality of luminance gradation images generated in step S121. The image generation unit 1112 may generate only the inspection image of the inspection region set in step S100, or may generate an inspection image including a peripheral region of the inspection region. The image generating unit 1112 generates the image information 113 obtained by converting the generated inspection image into data, and outputs the image information. 113 as the inspection image to the information processing device 120.

Similar to the measurement of the charge amount, the generation of the inspection image may be executed for each scanning range related to the electron beam 103. The Generation of the inspection image may be executed for every number of times of scanning with the electron beam 103.

In step S123, the information processing device 120 or the program in the information processing device 120 displays the inspection image 122 on a predetermined region of the user interface 121 based on the image information 113 input from the image generation unit 1112.

In step S130, for example, the control block 117 determines whether to end the measurement of the charge amount and the generation of the inspection image based on the measurement condition set in step S100. For example, the control block 117 performs the determination based on whether the electron beam 103 is emitted in the set scanning range, the set number of times of scanning, whether the measurement of the charge amount and the generation of the inspection image are performed, or the like.

When it is determined that the measurement condition is satisfied (Yes), the control block 117 ends the measurement of the charge amount and the generation of the inspection image. On the other hand, when it is determined that the measurement condition is not satisfied (No), the control block 117 continues the measurement of the charge amount and the generation of the inspection image. Then, the processings of steps S101 to S130 are repeatedly executed until the measurement condition is satisfied.

### <Main Effects of Present Embodiment=>

According to the present embodiment, the measurement of the charge amount of the sample 104 and the generation of the inspection image of the sample 104 are performed in parallel based on the electrical signal 107 output from the detector 106. According to this configuration, since the inspection time can be shortened, it is possible to achieve both improvement in throughput and maintenance of inspection accuracy.

According to the present embodiment, the plurality of detection elements 301 are two-dimensionally arranged in the detection region 300. According to this configuration, the reaching position of the secondary particles 105 can be accurately specified.

According to the present embodiment, the signal processing block 115 includes the plurality of reaching position detection circuits 1081, the signal intensity detection circuit 1082, the charge amount measurement unit 1111, and the image generation unit 1112. According to this configuration, a hardware-only configuration and a hardware and software configuration can be combined for each functional block. Accordingly, the signal processing block 115 can be efficiently configured.

### Second Embodiment

Next, a second embodiment will be described. In the present embodiment, a method for measuring a wide range of charge amount (also referred to as “global charge amount”) of the sample 104 and a local charge amount (“local charge amount”) of the sample 104 when a plurality of electron beams are simultaneously emitted will be described. Also in the present embodiment, the measurement of the charge amount and the generation of the inspection image are performed in parallel.

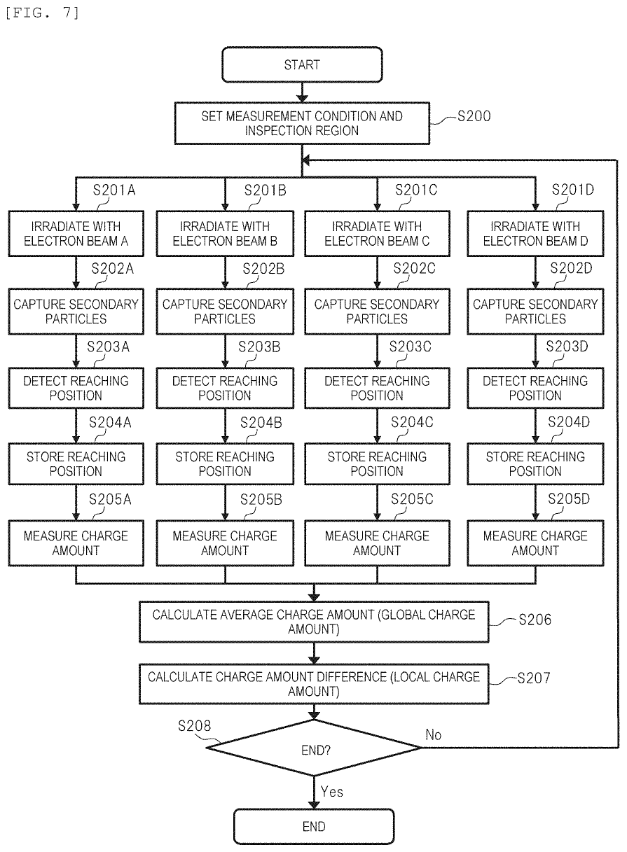

FIG. 6 is a diagram showing an example of a distribution of reaching positions of the secondary particles according to the second embodiment of the invention. FIG. 6 shows the reaching positions of the secondary particles 105 in the four detection regions 300A, 300B, 300C, and 300D. Reaching positions P100A to P102A indicate reaching positions in the detection region 300A corresponding to the electron beam 103 in a first direction. Reaching positions P100B-P102R indicate reaching positions in the detection region 300R corresponding to the electron beam 103 in a second direction. Reaching positions P1001 to P102C indicate reaching positions in the detection region 3001 corresponding to the electron beam 103 in a third direction. Reaching positions P100D-P102D indicate reaching positions in the detection region 300D corresponding to the electron beam 103 in a fourth direction.

The reaching positions P100A to P100D are each included in a region of the detection element 301 at an upper right part of each of the detection regions 300A to 300D in the figure, and the reaching positions P101A to P101D are each included in a region of the detection element 301 at a center of each of the detection regions 300A to 300D in the figure. The reaching positions P102A to P102C are each included in a region of the detection element 301 at a lower left part of each of the detection regions 300A to 300C in the figure. The reaching position 102D is included in a region of the detection element 301 at a center of the detection region 300D in the figure. These are merely examples.

In the multi-beam scanning electron microscope 100, detections of the reaching position of the secondary particles 105 with respect to the electron beam. 103 in respective directions (for example, the first direction to the fourth direction) are performed in parallel. Therefore, influences of the global charge amount of the entire sample 104 on the reaching position of the secondary particles 105 are substantially the same among the electron beams in respective directions. On the other hand, an influence of the local charge amount of the sample 104 on the reaching position of the secondary particles 105 differs depending on the direction of the electron beam. In consideration of such a situation, the global charge amount and the local charge amount are measured.

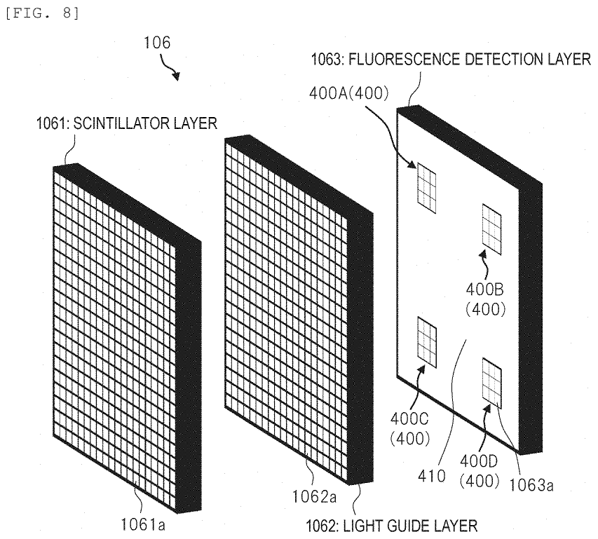

FIG. 7 is a flowchart showing an example of a method for measuring a charge amount according to the second embodiment of the invention. First, in step S200, a measurement condition and an inspection region for the sample 104 are set as in step S100 of FIG. 5. In the present embodiment, a region corresponding to the detection regions 300A to 300D in FIG. 6 is set as the inspection region. That is, the detections of the secondary particles 105 generated by the plurality of electron beams 103 simultaneously emitted are performed in parallel.

Steps S201A to S205A, steps S201B to S205B, steps S201C to S205C, and steps S201D to S205D are executed in parallel.

Specifically, steps S201A to S205A are steps of performing measurement of the charge amount in the detection region. 300A based on irradiation with the electron beam. 103 in the first direction. In FIG. 7, the electron beam in the first direction is referred to as the electron beam A.

Steps S201B to S205B are steps of performing measurement of the charge amount in the detection region 300B based on irradiation with the electron beam 103 in the second direction. In FIG. 7, the electron beam in the second direction is referred to as the electron beam B.

Steps S201C to S205C are steps of performing measurement of the charge amount in the detection region 300B based on irradiation with the electron beam 103 in the third direction. In FIG. 7, the electron beam in the third direction is referred to as the electron beam C.

Steps S201D to S205D are steps of performing measurement of the charge amount in the detection region 300D based on irradiation with the electron beam 103 in the fourth direction. In FIG. 7, the electron beam in the fourth direction is referred to as the electron beam D.

In steps S201A, S201B, S201C, and S201D, the electron beams 103 in the first direction to the fourth direction are simultaneously emitted to the sample 104 in accordance with various conditions such as the measurement condition and the inspection region set in step S200.

In steps S202A, S202B, S2025, and S202D, the detections of the secondary particles 105 generated by the irradiation with the electron beam 103 are performed in parallel. Specifically, in step S202A, the secondary particles 105 generated from the sample 104 by the electron beam 103 in the first direction reach the detection element 301 of the detection region 300A and are captured. In step S202B, the secondary particles 105 generated from the sample 104 by the electron beam 103 in the second direction reach the detection element. 301 of the detection region 300B and are captured.

In step S2025, the secondary particles 105 generated from the sample 104 by the electron beam 103 in the third direction reach the detection element. 301 of the detection region 3005 and are captured. In step S202D, the secondary particles 105 generated from the sample 104 by the electron beam 103 in the fourth direction reach the detection element 301 of the detection region 300D and are captured.

Since the sample 104 is not charged at the start of the measurement, the reaching positions of the secondary particles 105 in the detection regions 300A, 300B, 3005, and 300D are respectively, for example, P100A, P100B, P100C, and P100D in FIG. 6. When the sample 104 starts to be charged by the irradiation with the electron beam 103, the trajectory of the secondary particles 105 is gradually changed, and the reaching positions of the secondary particles 105 in the detection regions 300A, 300B, 300C, and 300D are changed respectively, for example, to P101A, P101B, P101C, and P101D in FIG. 6. Further, when the irradiation time elapses, the reaching positions of the secondary particles 105 in the detection regions 300A, 300B, 300C, and 300D are changed respectively to, for example, P102A, P102B, P102C, and P102D in FIG. 6.

In steps S203A, S203B, S2030, and S203D, the reaching position of the secondary particles 105 in each of the detection regions 300A, 300B, 3000, and 300D is detected. The processings in steps S203A, S203B, S203C, and S203D are similar to those in step S110 in FIG. 5. In each of the detection regions 300A, 300B, 300C, and 300D, the detection element. 301 supplemented with the secondary particles 105 outputs the electrical signal. 107 to the corresponding reaching position detection circuit 1081 and signal intensity detection circuit 1082.

When the electrical signal 107 is input from the corresponding detection regions 300A, 300B, 3000, and 300D, the corresponding reaching position detection circuit 1081 detects the reaching position of the secondary particles 105, and outputs the corresponding reaching positon signal 109 to the charge amount measurement unit 1111.

In steps S204A, S204B, S204C, and S204D, the reaching position signals 109 in the detection regions 300A, 300B, 300C, and 300D are stored in the storage device. Steps S204A, S204B, S204C, and S204D are similar to step S111 in FIG. 5.

In steps S205A, S205B, S205C, and S205D, the charge amount of the sample 104 is measured. The charge amount measurement unit 1111 detects the change reaching position of the secondary particles 105 for each of the detection regions 300A, 300B, 300C, and 300D based on the reaching position signal 109 stored in the storage device, and calculates (measures) the charge amount of the sample 104 in each of the detection regions 300A, 300B, 300C, and 300D based on the chance in reaching position. A method for measuring the charge amount in each of the detection regions 300A, 300B, 300C, and 300D is the same as that in step S112 of FIG. 5.

In step S206, the global charge amount of the sample 104 is calculated. The charge amount measurement unit 1111 calculates an average charge amount of the sample 104 by averaging the charge amounts of the sample 104 measured in the plurality of detection regions 300A, 300B, 300C, and 300D. Accordingly, the calculated average charge amount is the global charge amount.

In step S207, the local charge amount of the sample 104 in each of the detection regions 300A, 300B, 300C, and 300D is calculated. The charge amount measurement unit 1111 calculates a difference between the global charge amount and the charge amount of the sample 104 measured in each of the detection regions 300A, 300B, 300C, and 300D, and calculates the local charge amount of the sample 104 corresponding to each of the detection regions 300A, 300B, 300C, and 300D.

FIG. 6 illustrates a change in reaching position of the secondary particles 105 in the detection regions 300A, 300B, 300C, and 300D corresponding to four electron beams 103 emitted in the first direction to the fourth direction. In the example in FIG. 6, the change in reaching position of the secondary particles 105 in the detection regions 300A, 300B, and 300C (P400A to 9401A to P402A, P400B to 940B to P402B, P400C to P401C to P402C) shows the same tendency, but the change in reaching position of the secondary particles in the detection region. 300D (P400D to P401D to P402D) is different from this.

Therefore, it can be seen that, when the charge amount is measured for each electron beam. 103, the charge amounts of the sample 104 in portions irradiated with the electron beam 103 in the first direction, irradiated with the electron beam 103 in the second direction, and irradiated with the electron beam 103 in the third direction are substantially the same, and the charge amount of the sample 104 in a portion irradiated with the electron beam 103 in the fourth direction is different from these.

Therefore, it can be said that the sample 104 in the portion irradiated with the electron beam in the first direction, the electron beam in the second direction, and the electron beam in the third direction is mainly global charged. On the other hand, it can be said that the sample 104 in the portion irradiated with the electron beam in the fourth direction is in a state in which the local charge is superimposed on global charge.

After step S207, similar to step S113 in FIG. 5, the charge amount measurement unit 1111 may output, as the charge amount information 112, the measured global charge amount and local charge amount to the information processing device 120, and display the global charge amount and the local charge amount as the sample charge amount 123. In parallel with the measurement of the global charge amount and the local charge amount, the inspection image in each inspection region is also generated. The inspection image is generated for each detection region, for example.

In step S208, similar to step S130 in FIG. 5, it is determined whether the measurement of the charge amount and the generation of the inspection image are ended. When a predetermined measurement condition is satisfied (Yes), the control block 117 ends the measurement of the charge amount and the generation of the inspection image. On the other hand, when the measurement condition not satisfied. (No), the control block 117 continues the measurement of the charge amount and the generation of the inspection image. Then, until the measurement condition is satisfied, the processings of steps 2201A to S205A, S201B to S205B, S201C to 2205C, S201D to S205D, and S206 to S207 are repeatedly executed.

In the present embodiment, the global charge amount and the local charge amount are measured based on the charge amount measured in each of the detection regions 300A, 300B, 300C, and 300D, but the invention is not limited thereto. In accordance with the first embodiment, steps S206 to S207 in FIG. 7 may be omitted as appropriate.

### <Main Effects of Present Embodiment>

According to the present embodiment, the sample 104 is irradiated with the plurality of electron beams simultaneously. According to this configuration, the charge amounts of the sample 104 in the plurality of inspection regions can be simultaneously measured. The inspection image for each detection region can be simultaneously generated.

According to the present embodiment, the global charge amount and the local charge amount of the sample 104 are measured based on the charge amount measured fo each detection region. According to this configuration, the difference between the charge amount measured in each detection region and the global charge amount is clear, and a deviation of the charge amount can be easily detected.

### Third Embodiment

Next, a third embodiment will be described. In the present embodiment, the configuration of the detector is different from that of the previous embodiments. Specifically, the secondary particles 105 reaching the detector are converted into fluorescence, and the fluorescence is converted into an electrical signal.

FIG. 8 is an exploded perspective view showing an example of the configuration of the detector according to the third embodiment of the invention. As shown in FIG. 8, the detector 106 according to the present embodiment includes a scintillator layer 1061, a light guide layer 1062, and a fluorescence detection layer 1063. In FIG. 8, the scintillator layer 1061, the light guide layer 1062, and the fluorescence detection layer 1063 are illustrated in a state of being separated from each other.

A plurality of scintillators 1061a are two-dimensionally arranged in the scintillator layer 1061 so as to cover a detection region 400 described later. Specifically, the plurality of scintillators 1061a may be arranged so as to cover the entire surface of the fluorescence detection layer 1063 as shown in FIG. 1, or may be arranged so as to cover only the detection region 400, or only a region including the detection region 400 and a periphery of the detection region 400. The respective scintillators 1061a convert the secondary particles 105 reaching from the sample 104 into fluorescence, and output the fluorescence to a light guide layer 1062 side.

A plurality of light guides 1062a are two-dimensionally arranged in the light guide layer 1062 so as to cover the detection region 400 described later. Specifically, the plurality of light guides 1062a may be arranged so as to cover the entire surface of the fluorescence detection layer 1063 as shown in FIG. may be arranged so as to cover only the detection region 400, or only a region including the detection region 400 and the periphery of the detection region 400. It is desirable that the plurality of light guides 1062a correspond to the plurality of scintillators 1061a in a one-to-one manner, but the invention is not limited thereto.

The fluorescence detection layer 1063 is a functional block that converts the fluorescence guided by the light guide layer 1062 into an electrical signal. The fluorescence detection layer 1063 includes the detection region 400, and the fluorescence is converted into an electrical signal in the detection region 400. Specifically, a plurality of fluorescence detection elements 1063a are two-dimensionally arranged in the detection region 400. The fluorescence detection element 1063a converts the fluorescence guided by the light guide layer 1062 into an electrical signal. The fluorescence detection element 1063a outputs the electrical signal to the signal processing block 115 shown in FIG. 1 and the like.

FIG. 8 shows four detection regions 400 (400A, 400B, 400C, and 400D). The detection regions 400A, 400B, 400C, and 400D are provided, for example, corresponding to the electron beams 103 in the first direction to the fourth direction. The number of detection regions 400 in the fluorescence detection layer 1063 may be more than four or less than four.

In the multi-beam scanning electron microscope 100, depending on distances (that is, distances between the inspection regions in the sample 104) between the electron beams 103 emitted in each direction (for example, the first to fourth directions), there are regions where the secondary particles 105 reach and regions where the secondary particles 105 hardly reach.

For example, each inspection region of the sample 104 by the electron beam 103 is a region of 1 μm square, and the distance between the inspection regions is 100 μm. In this case, when the secondary particles generated from each inspection region are captured by one detector 106, a region where the secondary particles 105 reach is concentrated in a region less than 0.1% of a light receiving surface of the detector, and the secondary particles 105 hardly reach a region which is the remaining 99.9% or more of the light receiving surface.

In the first and second embodiments, the detection elements 301 are two-dimensionally arranged in the entire region of the detector 106. Since the reaching position detection circuits 1081 corresponding to the detection elements 301 in a one-to-one manner are provided, a circuit scale and a cost increase.

Therefore, in the present, embodiment, as shown in FIG. 8, each of the detection regions 400A, 400B, 400C, and 400D is provided in narrow regions at positions separated from each other in consideration of the region where the secondary particles 105 reach.

Therefore, the fluorescence detection layer 1063 includes the detection regions 400A, 400B, 400C, and 400D in which the fluorescence detection elements 1063a are densely arranged in the region where the secondary particles 105 reach and a region 410 where the secondary particles 105 hardly reach, and the fluorescence detection elements 1063a are sparse or absent.

On the other hand, as shown in FIG. 8, the scintillator layer 1061 and the light guide layer 1062 may be arranged such that entire main surfaces of the scintillators 1061a and the light guides 1062a are finely subdivided. Therefore, when the scintillator layer 1061, the light guide layer 1062, and the fluorescence detection layer 1063 are combined, it is not necessary to perform highly accurate alignment. This is because, in the scintillator layer 1061 and the light guide layer 1062, the entire main surfaces are subdivided, and can be associated with the fluorescence detection elements 1063a at any position.

Also in the present embodiment, a shape of each layer viewed from the incident direction of the secondary particles 105 is not limited to the example in FIG. 8. Specifically, as described in the first embodiment, the shape of each layer is not limited to a flat surface, or may be the shape in which the periphery is curved toward the sample 104 with respect to the center. The arrangement of the scintillators 1601a, the light guides 1062a, and the fluorescence detection elements 1603a is not limited to a grid pattern as shown in FIG. 8, or may be an arrangement in which positions of adjacent elements and the like are shifted.

In the region 410 in which the fluorescence detection elements 1063a are sparse or absent, a space where the fluorescence detection elements 1063a can be installed may be formed by a spacer. On the contrary, in the region 410 in which the fluorescence detection elements 1063a are sparse or absent, the space where the fluorescence detection elements 1063a can be installed may be filled with resin or the like.

### <Main Effects of Present Embodiment>

According to the present embodiment, the detector 106 is provided with the scintillator layer 1061, the light guide layer 1062, and the fluorescence detection layer 1063. According to this configuration, the secondary particles 105 can be converted into the electrical signal 107 through the fluorescence. According to this configuration, the fluorescence can be efficiently guided to the fluorescence detection layer 1063 by the light guide 1062a. According to this configuration, since the secondary particles 105 do not directly hit the fluorescence detection layer 1063, the fluorescence detection element 1063a can be protected.

According to the present embodiment, the scintillators 1061a and the light guides 1062a are arranged so as to cover the detection region 400. According to this configuration, the fluorescence output from the scintillator 1061a can be efficiently guided to the detection region 400.

According to the present embodiment, the scintillators 1061a are arranged so as to cover the entire surface of the fluorescence detection layer 1063, and the light guides 1062a are arranged so as to cover the entire surface of the fluorescence detection layer 1063. According to this configuration, configurations of the scintillator layer 1061 and the light guide layer 1062 can be prevented from becoming complicated.

According to the present embodiment, the fluorescence detection layer 1063 is provided with the detection regions 400A, 400B, 400C, and 400D in which the fluorescence detection elements 1063a are densely arranged, and the region 410 in which the fluorescence detection elements 1063a are sparse or absent. According to this configuration, the number of unnecessary fluorescence detection elements 1063a and the reaching position detection circuits 1081 that hardly capture the secondary particles 105 can be reduced. This also makes it possible to reduce the cost.

The invention not limited to the embodiments described above, and includes various modifications. A part of the configuration of one embodiment can be replaced with the configuration of another embodiment, and the configuration of another embodiment can be added to the configuration of one embodiment.

A part of the configuration of each embodiment may be added, deleted, or replaced with another configuration. Each member and the relative size described in the drawings are simplified and idealized in order to easily understand the invention, and are more complicated in terms of implementation.

### REFERENCE SIGN LIST

100 . . . multi-beam scanning electron microscope (charged particle beam device)
101 . . . electron gun (charged particle irradiation source)
104 . . . sample
105 secondary particles
106 . . . detector
107 . . . electrical signal
109 . . . reaching position signal
110 . . . intensity signal
115 . . . signal processing block
300, 400 . . . detection region
301 . . . detection element
1061 . . . scintillator layer
1061a . . . scintillator
1062 . . . light guide layer
1062a . . . light guide
1063 . . . fluorescence detection layer
1063a . . . fluorescence detection element
1081 . . . reaching position detection circuit
1082 . . . signal intensity detection circuit
1111 . . . charge amount measurement unit
1112 . . . image generation unit

1. A charged particle beam device, comprising:
a charged particle irradiation source configured to irradiate a sample with a charged particle beam;
a detector having a detection region corresponding to the charged particle beam and configured to output an electrical signal corresponding to a reaching position when secondary particles generated from the sample by irradiating the sample with the charged particle beam reach the detection region; and
a signal processing block configured to perform measurement of a charge amount of the sample by the charged particle beam and generation of an inspection image of the sample in parallel based on the electrical signal output from the detector.

2. The charged particle beam device according to claim 1, wherein
in the detection region, a plurality of detection elements are two-dimensionally arranged.

3. The charged particle beam device according to claim 2, wherein
the signal processing block includes
a plurality of reaching position detection circuits provided corresponding to the respective detection elements and configured to detect the reaching position of the secondary particles to generate a corresponding reaching position signal,
a signal intensity detection circuit provided corresponding to the detection region and configured to detect a signal intensity of the electrical signal in the corresponding detection region to generate a corresponding intensity signal,
a charge amount measurement unit configured to measure the charge amount of the sample based on the reaching position signal, and
an image generation unit configured to generate the inspection image based on the intensity signal.

4. The charged particle beam device according to claim 1, wherein
the charged particle irradiation source is configured to simultaneously irradiate a plurality of charged particle beams, and
the detector has a plurality of the detection regions corresponding to the respective charged particle beams.

5. The charged particle beam device according to claim 4, wherein
the signal processing block is configured to perform the measurement of the charge amount of the sample and the Generation of the inspection image in parallel for each detection region.

6. The charged particle beam device according to claim 5, wherein
the signal processing block is configured to measure a global charge amount of the sample by averaging charge amounts of the sample measured in the plurality of detection regions, calculate a difference between the charge amounts of the sample measured in the respective detection regions and the global charge amount, and measure a local charge amount of the sample corresponding to the respective detection regions.

7. The charged particle beam device according to claim 1, wherein
the detector includes
a scintillator layer configured to output fluorescence when the secondary particles reach,
a fluorescence detection layer having the detection region and configured to convert the fluorescence into the electrical signal is the detection region, and
a light guide layer configured to guide the fluorescence to the fluorescence detection layer.

8. The charged particle beam device according to claim 7, wherein
in the detection region, a plurality of fluorescence detection elements are two-dimensionally arranged,
in the scintillator layer, plurality of scintillators that convert the secondary particles into the fluorescence are arranged so as to cover the detection region, and
in the light guide layer, a plurality of light guides that guide the fluorescence to the fluorescence detection layer are arranged so as to cover the detection region.

9. The charged particle beam device according to claim 8, wherein
the plurality of scintillators are arranged so as to cover an entire surface of the fluorescence detection layer, and
the plurality of light guides are arranged so as to cover the entire surface of the fluorescence detection layer.

10. The charged particle beam device according to claim 1, further comprising:
a deflector configured to perform scanning with the charged particle beam, wherein
the deflector is configured to scan, with the charged particle beam, an inspection region of the sample corresponding to the detection region.

11. The charged particle beam device according to claim 10, wherein
the signal processing block is configured to perform the measurement of the charge amount of the sample for each scanning range of the charged particle beam.

12. The charged particle beam device according to claim 10, wherein
the signal processing block is configured to perform the measurement of the charge amount of the sample for every number of times of scanning with the charged particle beam.

13. The charged particle beam device according to claim 1, wherein
the charged particle beam is an electron beam.
